(19) United States
(12) Patent Application Publication
(10) Pub. No.: US 2025/0389757 A1
(43) Pub. Date: Dec. 25, 2025

(54) SEMICONDUCTOR DEVICE

(71) Applicant: ROHM CO., LTD., Kyoto-shi (JP)

(72) Inventors: Hiroaki SAWAOKA, Kyoto (JP); Kazumasa NISHIO, Kyoto (JP); Kosaku ADACHI, Kyoto (JP)

(21) Appl. No.: 19/238,956

(22) Filed: Jun. 16, 2025

(30) Foreign Application Priority Data
Jun. 25, 2024 (JP) 2024-102137

(51) Int. Cl. G01R 19/00; G01R 15/04

(52) U.S. Cl. CPC G01R 19/0084; G01R 15/04

(57) ABSTRACT

The semiconductor device includes: an insulating layer provided on a semiconductor substrate; a first resistor embedded in the insulating layer and electrically connected to a node on a first potential side; a second resistor embedded in the insulating layer; a third resistor embedded in the insulating layer; and a reference electrode electrically connected to a node on a second potential side of the third resistor. An absolute value of the first potential is greater than an absolute value of the second potential. The first resistor, the second resistor, and the third resistor are connected in series. The first resistor is formed by connecting N resistors in parallel, the second resistor is formed by connecting M resistors in parallel, and the third resistor is formed by connecting L resistors in parallel, with N<L and M<L satisfied.

### CROSS-REFERENCE TO RELATED APPLICATIONS

The present invention claims priority under 35 U.S.C. § 119 to Japanese Patent Application No. 2024-102137, filed on Jun. 25, 2024. The entire contents of the above-identified application are hereby incorporated by reference.

### TECHNICAL FIELD

The present disclosure relates to a semiconductor device.

### BACKGROUND

International Publication No. WO 2023/085026 discloses a semiconductor device including a plurality of resistor elements.

### BRIEF DESCRIPTION OF THE DRAWINGS

FIG. 1 is a plan view of a semiconductor package in which a high voltage detection device is mounted.

FIG. 2 is a circuit diagram of a high voltage detection device.

FIG. 3A is a circuit diagram of a first example of a resistor and FIG. 3B is a circuit diagram of a second example of the resistor.

FIG. 4 is a circuit diagram of a resistor in the vicinity of a reference electrode.

FIG. 5 is a diagram illustrating a connection relationship between resistors and electrodes in a low-resistance part.

FIG. 6A shows a vertical sectional configuration of the resistor along a position through resistor elements, and FIG. 6B shows a vertical sectional configuration of the resistor along a position through a reference electrode.

FIG. 7 is a diagram illustrating a connection relationship between resistor elements and electrodes in a low-resistance part.

FIG. 8 is a plan view of multiple resistor elements.

FIG. 9 is a plan configuration diagram of a resistor provided with dummy wiring.

FIG. 10 is a diagram illustrating a vertical sectional configuration of the resistor at a position passing through the dummy wiring.

### DETAILED DESCRIPTION

The various exemplary embodiments will be described in detail with reference to the drawings below. In the drawings, the same reference numerals will be used for the same or equivalent parts, and redundant explanations will be omitted.

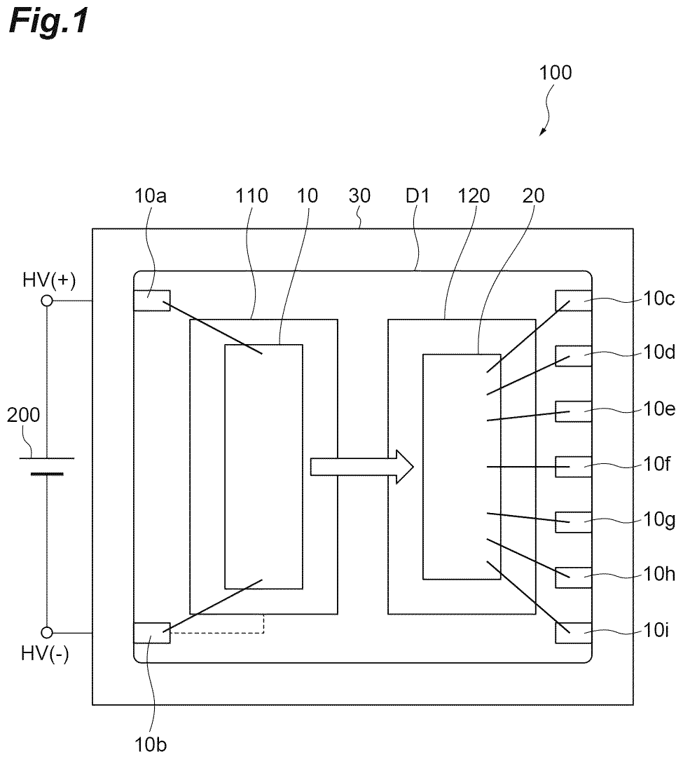

FIG. 1 is a plan view of a semiconductor package 100 in which a high voltage detection device is mounted.

In the figure, the state with the upper lid member removed is shown.

The semiconductor package 100 includes a case 30 having a recess DI. The case 30 is made of an insulating material such as resin or ceramic. The semiconductor package 100 includes a resistor chip 10 (semiconductor device) disposed on a first die pad 110 in the recess D1, and an amplifier chip 20 (semiconductor device) disposed on a second die pad 120 in the recess D1. The recess D1 of the semiconductor package 100 is sealed at its opening end by a lid member (not shown), and the interior of the recess D1 is made into a sealed space. The lid member may be made of an insulating material such as resin; the recess D1 may be filled with a gas or with an insulating material. Appropriate potentials, such as the ground potential, are applied to the first die pad 110 and the second die pad 120 via a lead frame. If necessary, for example, the potential of the first die pad 110 may be set to a high potential.

An output voltage of the resistor chip 10 is input to the amplifier chip 20. The amplifier chip 20 outputs a voltage corresponding to the detected voltage.

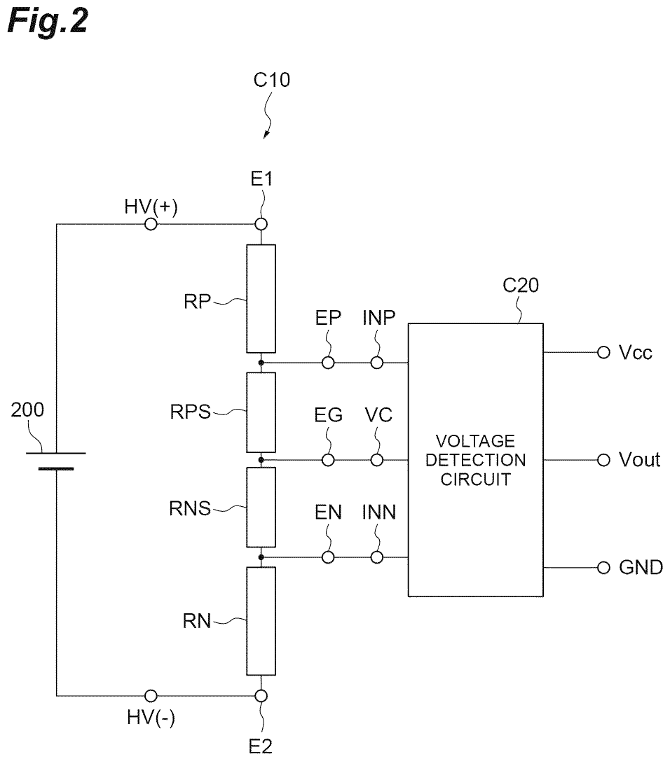

A positive terminal of a battery 200 is electrically connected to a first inner lead 10a and is connected through a bonding wire to a first electrode E1 (see FIG. 2) of the resistor chip 10. A negative terminal of the battery 200 is electrically connected to a second inner lead 10b and is connected through a bonding wire to a second electrode E2 (see FIG. 2) of the resistor chip 10.

Each terminal of the amplifier chip 20 can be connected via bonding wires to a third inner lead 10c, a fourth inner lead 10d, a fifth inner lead 10e, a sixth inner lead 10f, a seventh inner lead 10g, an eighth inner lead 10h, and a ninth inner lead 10i.

For example, a power supply voltage Vcc is applied to the third inner lead 10c and is input to the amplifier chip 20. A ground potential GND is applied to the ninth inner lead 10i and is input to the amplifier chip 20. The sixth inner lead 10f can output an output voltage Vout. From the fourth inner lead 10d, a monitor signal corresponding to the potential of a first output electrode EP (see FIG. 2) can be output. From the eighth inner lead 10h, a monitor signal corresponding to the potential of a second output electrode EN (see FIG. 2) can be output. The fifth inner lead 10c and the seventh inner lead 10g can be used for other purposes as needed.

FIG. 2 is a circuit diagram of a high voltage detection device. The high voltage detection device includes a resistor circuit C10 (voltage divider circuit) and a voltage detection circuit C20. The resistor chip 10 described above includes the resistor circuit C10, and the amplifier chip 20 includes the voltage detection circuit C20. A first input terminal HV (+) of the resistor circuit C10 is electrically connected to the positive terminal of the battery 200, and a second input terminal HV (−) of the resistor circuit C10 is electrically connected to the negative terminal of the battery 200. The first input terminal HV (+) is electrically connected to a first electrode E1 (electrode pad), and the second input terminal HV (−) is electrically connected to a second electrode E2 (electrode pad).

The resistor circuit C10 includes a first high-resistance part RP (a first resistor), a first low-resistance part RPS, a second low-resistance part RNS, and a second high-resistance part RN (a second resistor). Between the first electrode E1 and the second electrode E2, these resistor parts are connected in series in the order of the first high-resistance part RP, the first low-resistance part RPS, the second low-resistance part RNS, and the second high-resistance part RN. The first high-resistance part RP and second high-resistance part RN function to reduce a high voltage and each has a high resistance value. The first low-resistance part RPS and the second low-resistance part RNS function to detect voltage, and each has a relatively low resistance value compared to the high-resistance parts.

An exemplary value of the resistance of one high-resistance part is 500 MΩ, but it may be set to 1 MΩ or more and 1000 MΩ or less. The resistance value of the high-resistance part may also be set to 100 MΩ or more and 800 MΩ or less. The resistance value of the high-resistance part may also be set to 300 MΩ or more and 600 MΩ or less. The resistance value may have the capability to withstand high voltage and enable voltage detection.

The resistance value of one low-resistance part (RPS or RNS) is at or below K % of the resistance value of the high-resistance part. Exemplary values for K % include 5%, 3%, 1%, 0.5%, 0.3%, 0.1%, 0.05%, or 0.01%, and the resistance of the low-resistance part may, for instance, be set to 0.01 MΩ to 10 MΩ.

A connection point between the first high-resistance part RP and the first low-resistance part RPS is electrically connected to a first output electrode EP (electrode pad). A connection point between the second high-resistance part RN and the second low-resistance part RNS is electrically connected to a second output electrode EN (electrode pad). A reference electrode EG (electrode pad) is electrically connected between the first low-resistance part RPS and the second low-resistance part RNS.

Since the resistor circuit C10 is a voltage divider circuit, it can provide a voltage determined by the resistance between any two selected nodes in the resistor circuit C10. The first output electrode EP is electrically connected to a first input terminal INP of the voltage detection circuit C20, and the second output electrode EN is electrically connected to a second input terminal INN of the voltage detection circuit C20. The reference electrode EG is electrically connected to a reference terminal VC of the voltage detection circuit C20. The potential of the reference terminal VC may be set to, for example, the ground potential. The voltage detection circuit C20 can output an output voltage Vout. The output voltage Vout can be the sum of the magnitude of the potential difference between the first input terminal INP and the reference terminal VC and that between the second input terminal INN and the reference terminal VC. The voltage detection circuit C20 can include a source follower (amplifier) that amplifies the voltage input from the input terminals and may include a differential amplifier circuit for adding the magnitudes of the input voltages. The voltage detection circuit C20 is provided with an input terminal for the power supply voltage Vcc to drive its internal circuit, and an input terminal to set the ground potential GND.

The resistor circuit C10 can include dummy resistors.

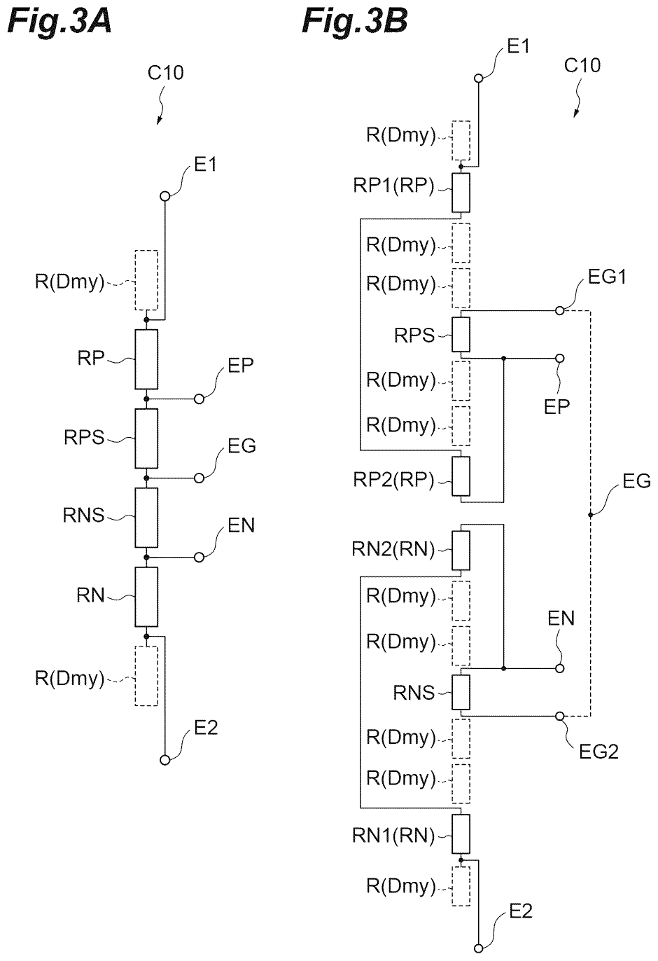

FIG. 3A shows a circuit diagram of a first example of a resistor, and FIG. 3B shows a circuit diagram of a second example of a resistor.

In the resistor circuit C10 of FIG. 3A, one end of a dummy resistor R(Dmy) is electrically connected to the input side of the first high-resistance part RP, and a dummy resistor R(Dmy) is electrically connected to the input side of the second high-resistance part RN. The dummy resistor need not necessarily be electrically connected to the resistor. For example, resistor elements at both ends of a resistor chip may differ in resistor characteristics from those in the central portion. By treating these resistors as dummy resistors, detection accuracy can be improved.

The resistor circuit C10 of FIG. 3B is a modified configuration of the circuit of the first example. In this example, the first high-resistance part RP is composed of a high-resistance part RPI and a high-resistance part RP2 connected in series, and the second high-resistance part RN is composed of a high-resistance part RN1 and a high-resistance part RN2 connected in series. The reference electrode EG is split into a first reference electrode EG1 and a second reference electrode EG2, and these electrodes may be electrically connected on the voltage detection circuit side. Furthermore, compared with the circuit of the first example, one or more dummy resistors R(Dmy) are also provided between each of the resistor parts.

A dummy resistor is a resistor to which no current flows during normal operation and is provided to maintain electrical equivalence in the resistor circuit C10, maintain electrical stability, or reduce error factors when manufacturing resistors during production processes. The circuit configuration of the high voltage detection device is not limited to these examples; as long as the basic voltage detection function is preserved, the shapes and arrangements of the resistors may be modified as appropriate.

The high voltage detection device described above can be housed within a single semiconductor package as explained. The functions of each circuit can also be split between the resistor chip and the amplifier chip and mounted within the package. It is also possible to move some circuit components to either chip, or to integrate them into a single chip.

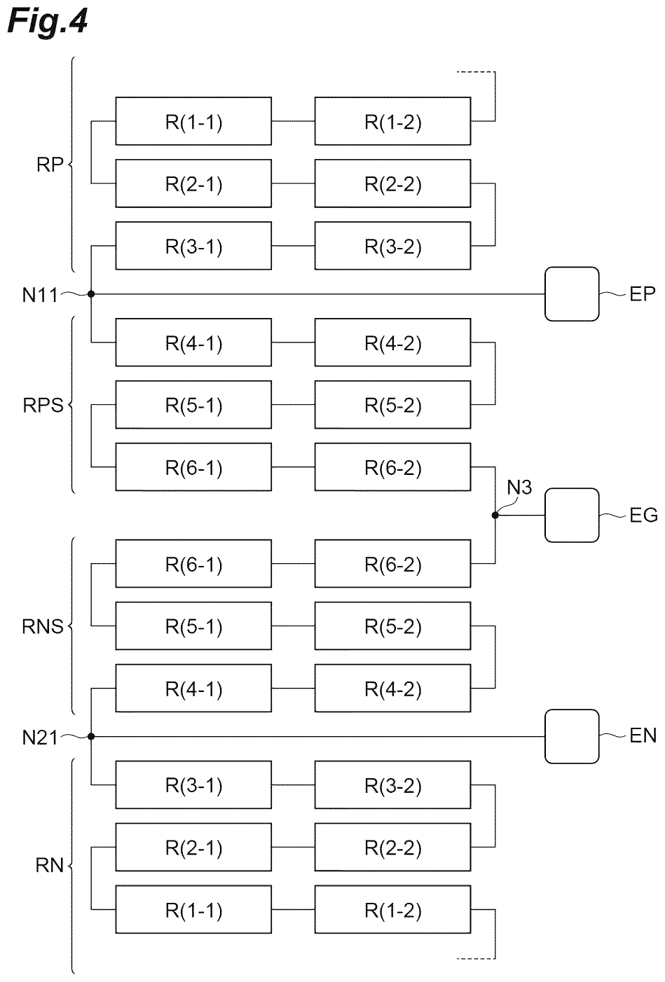

FIG. 4 is a circuit diagram of a resistor in the vicinity of the reference electrode.

On the side to which a positive high potential is applied, a first high-resistance part RP includes a first resistor R(1), a second resistor R(2), and a third resistor R(3), all connected in series. One resistor can be composed of at least two resistor elements (resistors, resistor layers) connected in series. For example, the first resistor R(1) can be formed by connecting two resistor elements R(1-1) and R(1-2) in series. Likewise, the kth resistor R(k) can be formed by connecting two resistor elements R(k-1) and R(k-2) in series, where k is a natural number.

On the side to which a negative high potential is applied, a second high-resistance part RN includes a first resistor R(1), a second resistor R(2), and a third resistor R(3), connected in series.

A first low-resistance part RPS includes a fourth resistor R(4), a fifth resistor R(5), and a sixth resistor R(6), all connected in series. Likewise, a second low-resistance part RNS includes a fourth resistor R(4), a fifth resistor R(5), and a sixth resistor R(6), all connected in series.

A node (N11) between the first high-resistance part RP and the first low-resistance part RPS is connected to the first output electrode EP.

A node (N21) between the second high-resistance part RN and the second low-resistance part RNS is connected to the second output electrode EN.

The reference electrode EG is electrically connected to a node N3 between the resistor R(6) in the first low-resistance part RPS and the resistor R(6) in the second low-resistance part RNS. In other words, the reference electrode EG is electrically connected to one end of resistor R(6) in the first low-resistance part RPS and also to one end of resistor R(6) in the second low-resistance part RNS.

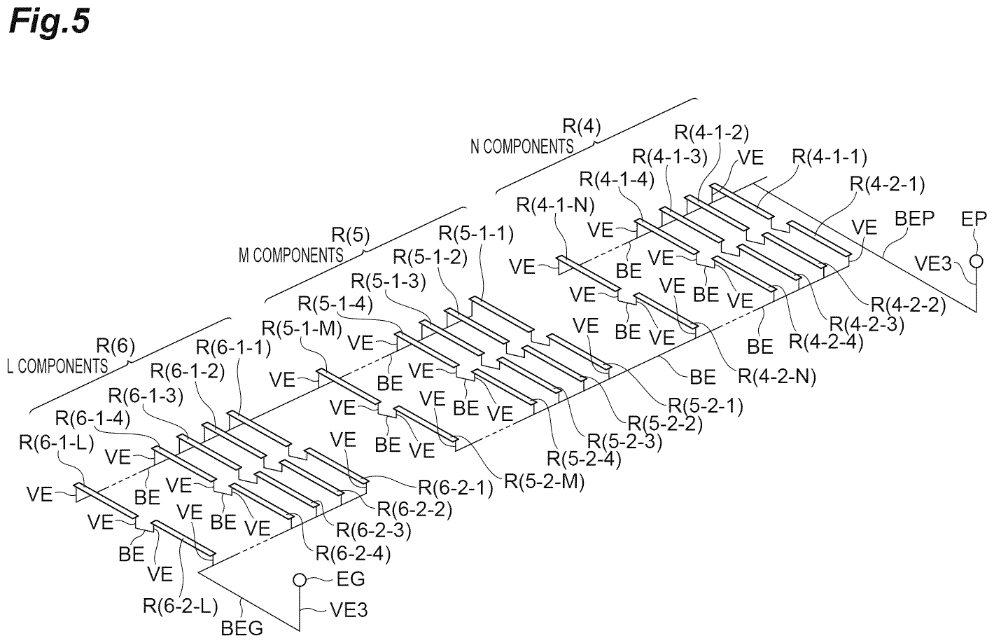

FIG. 5 is a diagram illustrating a connection relationship between resistor elements and electrodes in a low-resistance part.

In the first row (counting from the high-potential side) of the fourth resistor R(4), two resistor elements R(4-1-1) and R(4-2-1) connected in series are disposed. In the Nth row (counting from the high-potential side) of the fourth resistor R(4), two resistor elements R(4-1-N) and R(4-2-N) connected in series are disposed. The combined resistance of the resistor elements in a single row can be considered one resistor. In that case, the fourth resistor R(4) includes N resistors.

In the first row (counting from the high-potential side) of the fifth resistor R(5), two resistor elements R(5-1-1) and R(5-2-1) connected in series are disposed. In the Mth row (counting from the high-potential side) of the fifth resistor R(5), two resistor elements R(5-1-M) and R(5-2-M) connected in series are disposed. Considering the combined resistance of the resistor elements in each row as one resistor, the fifth resistor R(5) includes M resistors.

In the first row (counting from the high-potential side) of the sixth resistor R(6), two resistor elements R(6-1-1) and R(6-2-1) connected in series are disposed. In the Lth row (counting from the high-potential side) of the sixth resistor R(6), two resistor elements R(6-1-L) and R(6-2-L) connected in series are disposed. Considering the combined resistance of the resistor elements in each row as one resistor, the sixth resistor R(6) includes L resistors.

The upper surface of the via electrode VE is connected to the lower surface of both ends of each resistor clement R, and the lower surface of the via electrode is connected to the buried electrode BE. Focusing on one row, the pair of resistor elements arranged in alignment is connected in series though via electrodes VE and a buried electrode.

In the fourth resistor R(4), focusing on the N resistors, one end of each resistor is connected to a common embedded electrode BE on one side via a via electrode VE located directly below it. The other end of each resistor is connected to a common embedded electrode BE on the other side via a via electrode VE located directly below it. That is, the N resistors are connected in parallel between the embedded electrode BE on one side and the embedded electrode BE on the other side. The common embedded electrode BE on one side in the fourth resistor R(4) is continuously connected to the first wiring BEP, and the end of the first wiring BEP is electrically connected to the first output electrode EP via a via electrode (VE3).

Focusing on the M resistors in the fifth resistor R(5), one terminal of each of these M resistors is connected, via a via electrode VE located directly beneath it, to a common buried electrode BE on one side. The other terminal of each of these M resistors is connected, via a via electrode VE located directly beneath it, to a common buried electrode BE on the other side. That is, the M resistors are connected in parallel between the buried electrode BE on one side and the buried electrode BE on the other side.

Focusing on the L resistors in the sixth resistor R(6), one terminal of each of these L resistors is connected, via a via electrode VE located directly beneath it, to a common buried electrode BE on one side. The other terminal of each of these L resistors is connected, via a via electrode VE located directly beneath it, to a common buried electrode BE on the other side. That is, the L resistors are connected in parallel between the buried electrode BE on one side and the buried electrode BE on the other side. The common buried electrode BE on the other side of the sixth resistor R(6) is continuously connected to a second wiring BEG, whose end is electrically connected via a via electrode (VE3) to the reference electrode EG.

When the number of resistors in the fourth resistor R(4) is N, in the fifth resistor R(5) is M, and in the sixth resistor R(6) is L, from the perspective of improving withstand voltage it is at least required that N<L and M<L be satisfied. Preferably, for better withstand voltage, N<M<L. Even when M<N<L holds, a certain effect is obtained.

In FIG. 5, the structure of the first low-resistance part RPS is described, but the structure of the second low-resistance part RNS is the same as that of the first low-resistance part RPS. However, in the first low-resistance part RPS, a positive potential is applied, while in the second low-resistance part RNS, a negative potential is applied. In the second low-resistance part RNS, an end portion of the first wiring BEP is electrically connected, via a via electrode (VE3), to the second output electrode EN (see FIG. 4).

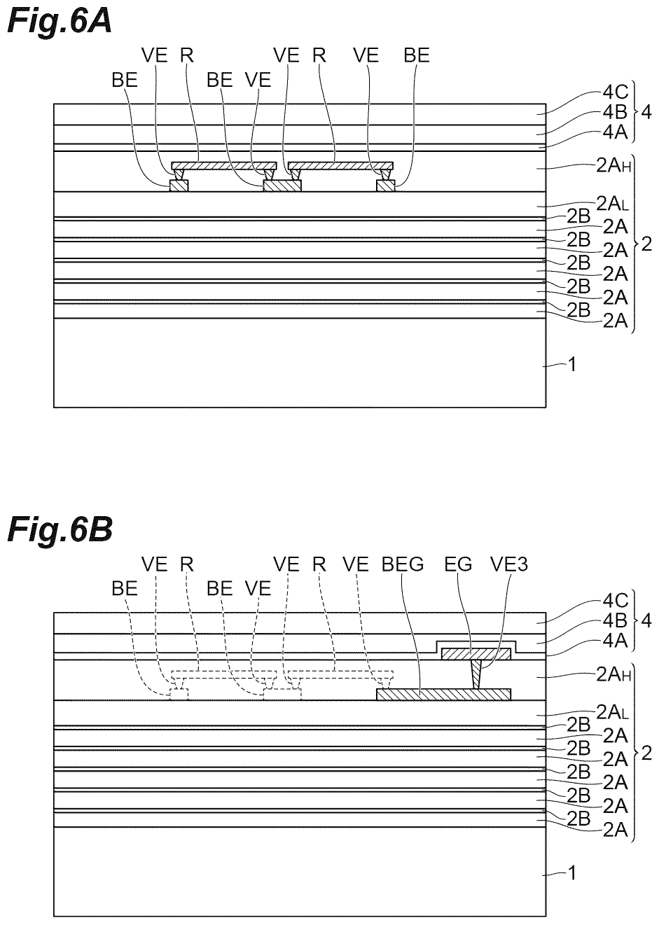

FIG. 6A shows a vertical sectional configuration of the resistor at a position that passes through a pair of adjacent resistor elements in the row direction, and FIG. 6B shows a vertical sectional configuration of the resistor at a position that passes through the reference electrode EG.

As shown in FIG. 6A, the semiconductor device includes an insulating layer 2 provided on a semiconductor substrate 1, and a plurality of resistors R (resistor elements, resistor layers) embedded in the insulating layer 2. All the resistors R are embedded in the insulating layer 2.

The insulating layer 2 has multiple stacked dielectric layers (a first dielectric layer 2A and a second dielectric layer 2B). At least one of these dielectric layers (the first dielectric layer 2A) includes silicon oxide. At least one of these dielectric layers (the second dielectric layer 2B) includes silicon nitride. In this example, the first dielectric layer 2A and the second dielectric layer 2B are alternately stacked. The silicon oxide here is SiO₂, but the elemental ratio may be changed as needed and may contain other elements. The silicon nitride here is Si₃N₄, but the elemental ratio may be changed as needed and may contain other elements. The thickness of the insulating layer 2 may be, for example, between 5 μm and 50 μm.

The insulating layer 2 includes a lower dielectric layer 2A_{L} formed on the second dielectric layer 2B located at the topmost position, and an upper dielectric layer 2A_{H} formed on the lower dielectric layer 2A_{L}. The exemplary materials of the lower dielectric layer 2A_{L}, and the upper dielectric layer 2A_{H} are the same as the material of the first dielectric layer 2A.

A protective film 4 is formed by successively stacking a first protective film 4A, a second protective film 4B, and a third protective film 4C on the insulating layer 2. The material of the first protective film 4A may be an inorganic insulating material such as silicon oxide or silicon nitride, for instance SiO₂. The second protective film 4B is formed on the first protective film 4A. The material of the second protective film 4B is an inorganic insulating material such as silicon oxide or silicon nitride, and it may be the same as the material of the first protective film 4A or different, for instance, silicon nitride. The third protective film 4C is made of a resin (insulating material) such as polyimide.

A buried electrode BE is arranged immediately beneath each resistor R, and each resistor R is electrically connected to the buried electrode BE via a via electrode (VE). (When the connection state of conductive elements is clear, “connected” may be stated simply, meaning both physical and electrical connection.)

As shown in FIG. 6B, a reference electrode EG is disposed on top of the insulating layer 2. A top end of a via electrode (VE3) is connected to the underside of the reference electrode EG, and the bottom end of that via electrode (VE3) is connected to the second wiring BEG. In the region immediately beneath resistor R, the second wiring BEG also functions as a buried electrode, and the resistor R is electrically connected via a via electrode VE to this buried electrode (the second wiring BEG).

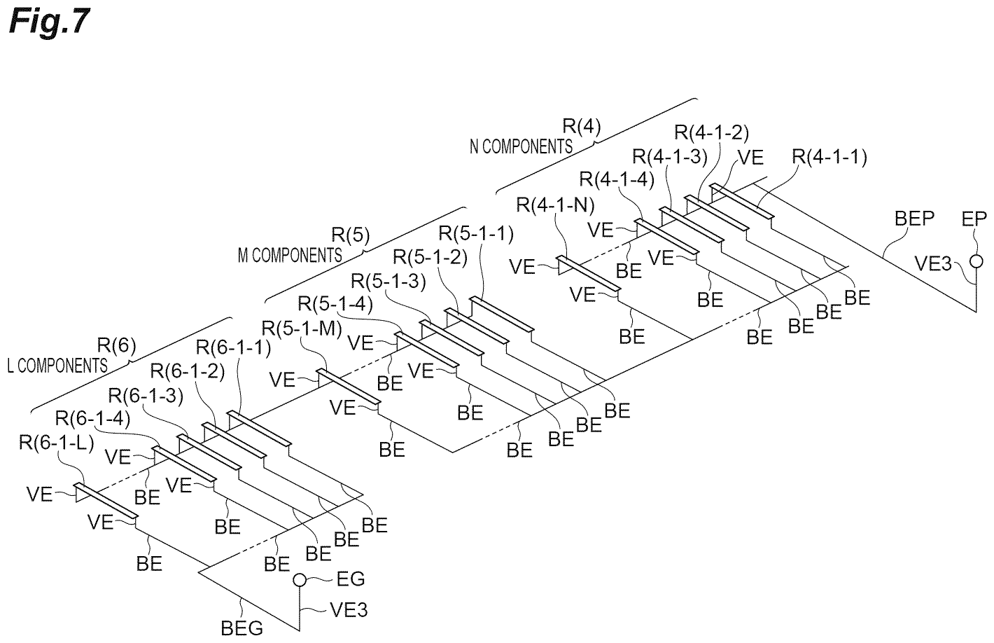

FIG. 7 is a diagram illustrating a connection relationship between resistor elements and electrodes in a low-resistance part.

In this example, the number of pairs of resistor elements in each row shown in FIG. 5 is reduced to one. That is, in the fourth resistor R(4), a resistor with one resistor element R in each row is connected in parallel with N resistors. In the fifth resistor R(5), a resistor with one resistor clement R in each row is connected in parallel with M resistors. In the sixth resistor R(6), a resistor with one resistor element R in each row is connected in parallel with L resistors.

Even if one side of the resistor elements is removed as in the present example, from the perspective of improving withstand voltage, it is at least required that N<L and M<L be satisfied. Preferably, for greater improvement in withstand voltage, N<M<L may be satisfied. From the perspective of improving withstand voltage, the arrangement M<N<L also offers a practical effect to some extent. The resistance value of each resistor element is the same, exemplified as 200 kΩ.

If one side of the resistor elements is removed, it is possible to place other resistor elements in the removed region.

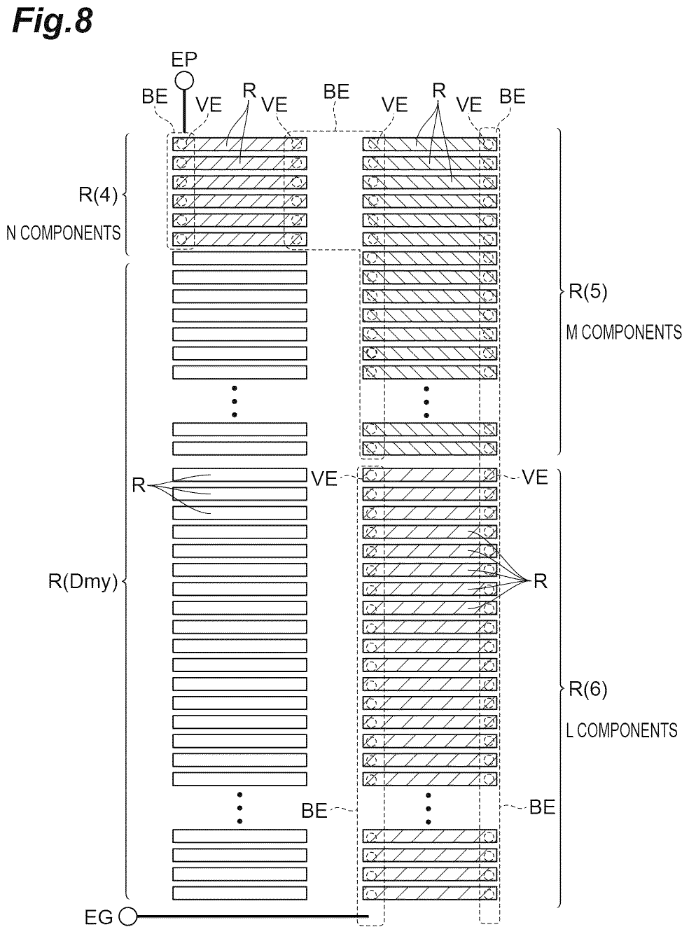

FIG. 8 is a plan view of multiple resistor elements.

The fourth resistor R(4) is formed by connecting N resistor elements R (resistors, resistor layers) in parallel between buried electrodes BE located at both ends. The fifth resistor R(5) is formed by connecting M resistor elements R in parallel between buried electrodes BE at both ends. The sixth resistor R(6) is formed by connecting L resistor elements R in parallel between buried electrodes BE at both ends. The fourth resistor (4), the fifth resistor R(5), and the sixth resistor R(6) are connected in series. In the first low-resistance part RPS (see FIG. 4), these resistors R(4) to R(6) are connected in series between the first output electrode EP and the reference electrode EG; in the second low-resistance part RNS (see FIG. 4), these resistors R(4) to R(6) are connected in series between the second output electrode EN and the reference electrode EG.

On extended lines along the row direction of individual resistor elements in part of the fifth resistor R(5), dummy resistors R(Dmy) are arranged. On extended lines along the row direction of the resistor elements in the sixth resistor R(6), dummy resistors R(Dmy) are arranged. The dummy resistor R(Dmy) is not electrically connected to the fourth to sixth resistors. One end of the dummy resistor R(Dmy) may be electrically connected to the fourth to sixth resistors, but it is not connected so as to allow current flow through the dummy resistor R(Dmy). Via electrodes and buried wiring may or may not be formed beneath the dummy resistor R(Dmy). Like the other resistors, the dummy resistor R(Dmy) includes a plurality of resistor elements R arranged in alignment.

Consider the improvement in withstand voltage. Assume that the resistor chip is fixed on a frame, and a noise high-frequency signal of 2000 V is introduced into that frame. The resistance value of each resistor element R is assumed to be uniformly 200 kΩ. Noise input to the frame is transferred to the resistor through parasitic capacitances between the semiconductor substrate and the resistor.

(Comparative Example 1) In Comparative Example 1 (N=M=L), assume that the fourth resistor R(4) has N=27 resistors, the fifth resistor R(5) has M=27 resistors, and the sixth resistor R(6) has L=27 resistors. The fourth resistor R(4) connects in parallel N resistors, each formed by connecting two 200 kΩ resistor elements in series. The fifth resistor R(5) connects in parallel M resistors, each formed by connecting two 200 kΩ resistor elements in series. The sixth resistor R(6) connects in parallel L resistors, each formed by connecting two 200 kΩ resistor elements in series. The third resistor R(3) is formed by connecting in series two 200 kΩ resistor elements. The combined resistance of the fourth resistor R(4) is about 14.8 kΩ. The combined resistance of the fifth resistor R(5) is about 14.8 kΩ. The combined resistance of the sixth resistor R(6) is about 14.8 kΩ. The combined resistance when the fourth and fifth resistors are connected in series is about 44.4 kΩ.

Under these conditions, the current flowing through each resistor element is about 1.607 mA in the third resistor R(3), 0.203 mA in the fourth resistor R(4), 1.569 mA in the fifth resistor R(5), and 3.504 mA in the sixth resistor R(6). Thus, the largest current flows in the sixth resistor R(6).

(Example 1) As Example 1 (N<M<L), assume that the fourth resistor R(4) has N=10 resistors, the fifth resistor R(5) has M=12 resistors, and the sixth resistor R(6) has L=27 resistors. The fourth resistor R(4) connects in parallel 10 resistors, each formed by a 200 kΩ resistor element, resulting in a combined resistance of 20 kΩ. The fifth resistor R(5) connects in parallel 12 resistors, each formed by a 200 kΩ resistor element, resulting in a combined resistance of about 16.67 kΩ. The sixth resistor R(6) connects in parallel 27 resistors, each formed by a 200 kΩ resistor element, resulting in a combined resistance of about 7.41 kΩ. The third resistor R(3) is formed by connecting in series two 200 kΩ resistor elements, and then connecting two of these series pairs in parallel. The combined resistance when the fourth to sixth resistors are connected in series is about 44.1 kΩ. Note that the combined resistance of the fourth resistor is greater than that of the fifth resistor, which is greater than that of the sixth resistor.

In that case, the current flowing through each resistor clement is 2.108 mA in the third resistor, 0.897 mA in the fourth resistor, 2.564 mA in the fifth resistor, and 2.869 mA in the sixth resistor. In other words, the current in the sixth resistor is reduced, and the current is dispersed among other resistors.

(Example 2) As Example 2 (N<M<L), assume that the fourth resistor R(4) has N=6 resistors, the fifth resistor R(5) has M=27 resistors, and the sixth resistor R(6) has L=54 resistors. The fourth resistor R(4) connects in parallel 6 resistors, each formed by a 200 kΩ resistor element, resulting in a combined resistance of about 33.33 kΩ. The fifth resistor R(5) connects in parallel 27 resistors, each formed by a 200 kΩ resistor element, resulting in a combined resistance of about 7.41 kΩ. The sixth resistor R(6) connects in parallel 54 resistors, each formed by a 200 kΩ resistor element, resulting in a combined resistance of about 3.70 kΩ. The third resistor R(3) is formed by connecting in series two 200 kΩ resistor elements and then connecting two of these series pairs in parallel. The combined resistance when the fourth to sixth resistors are connected in series is about 44.4 kΩ. Note that the combined resistance of the fourth resistor is greater than that of the fifth resistor, which is greater than that of the sixth resistor.

In that case, the current flowing through each resistor element is 2.242 mA in the third resistor, 1.153 mA in the fourth resistor, 1.370 mA in the fifth resistor, and 2.171 mA in the sixth resistor. The current in the sixth resistor is reduced further compared to Example 1, dispersed among the other resistors.

(Example 3) As Example 3 (M<N<L), assume N=14, M=10, L=21, with other conditions the same as Example 1. In that case, the current flowing through each resistor element is 1.920 mA in the third resistor, 0.361 mA in the fourth resistor, 3.172 mA in the fifth resistor, and 3.234 mA in the sixth resistor. That is, although the current in the sixth resistor is lower than in Comparative Example 1, and the current is dispersed among the other resistors, it is higher than in Example 1.

(Example 4) In Example 4 (M<N<L), the third resistor R(3) is assumed to be a resistor formed by connecting two 200 kΩ resistor elements in series, with each element being 200 kΩ, with other conditions being the same as in Example 3. The current flowing through each resistor element is 3.126 mA in the third resistor R(3), 0.254 mA in the fourth resistor R(4), 2.982 mA in the fifth resistor R(5), and 3.219 mA in the sixth resistor R(6). Thus, although the current in the sixth resistor R(6) is lower than in Comparative Example 1 and is dispersed among other resistors, it is higher than in Example 1.

(Comparative Example 2) As Comparative Example 2 (M<L<N), assume N=27, M=10, L=21, with other conditions the same as Example 4. Additionally, the fourth resistor R(4) is formed by connecting 27 resistors in parallel, each of which is made by connecting two resistor elements, each with a resistance of 200 kΩ, in series. In that case, the current flowing through each resistor element is 1.911 mA in the third resistor R(3), 0.472 mA in the fourth resistor R(4), 4.747 mA in the fifth resistor R(5), and 3.449 mA in the sixth resistor R(6). Hence, the current in the fifth resistor R(5) increased more than the maximum current (3.504 mA) in the sixth resistor R(6) in Comparative Example 1.

(Comparative Example 3) In Comparative Example 3 (N=0, M=L), N=0, M=18, and L=18, with other conditions being the same as in Example 1. The fifth resistor R(5) is formed by connecting 18 resistors in parallel, each of which is made by connecting two resistor elements, each with a resistance of 200 kΩ, in series. The sixth resistor R(6) is formed by connecting 18 resistors in parallel, each of which is made by connecting two resistor elements, each with a resistance of 200 kΩ, in series. In this case, the current flowing through one resistance element was 1.537 mA in the third resistor, 0.795 mA in the fifth resistor, and 3.706 mA in the sixth resistor. That is, the current in the sixth resistor increased more than the maximum current (3.504 mA) in the sixth resistor of Comparative Example 1.

(Comparative Example 4) In Comparative Example 4 (N=0, M=L), the third resistor R(3) is a resistor formed by connecting two 200 kΩ resistance elements in series, with other conditions being the same as in Comparative Example 3. In this case, the current flowing through one resistance element was 2.403 mA in the third resistor, 0.673 mA in the fifth resistor, and 3.689 mA in the sixth resistor. That is, the current in the sixth resistor increased more than the maximum current (3.504 mA) in the sixth resistor of Comparative Example 1.

(Comparative Example 5) As Comparative Example 5 (N=0, M=0, L=9), assume N=0, M=0, L=9, with other conditions matching Comparative Example 4. Additionally, the sixth resistor R(6) is formed by connecting 9 resistors in parallel, each of which is made by connecting two resistor elements, each with a resistance of 200 kΩ, in series. The current flowing through each resistor element is 4.106 mA in the third resistor R(3) and 2.875 mA in the sixth resistor R(6). The current in the third resistor R(3) increased more than the maximum current (3.504 mA) in the sixth resistor R(6) from Comparative Example 1.

(Comparative Example 6) In Comparative Example 6 (N=0, M=0, L=9), the third resistor R(3) is assumed to be formed by connecting two resistors in parallel, each of which is made by connecting two resistor elements, each with a resistance of 200 kΩ, in series. Other conditions are the same as in Comparative Example 5. The current flowing through each resistor element is 2.314 mA in the third resistor and 3.232 mA in the sixth resistor. The current in the sixth resistor R(6) is lower than the maximum current of 3.504 mA in the sixth resistor R(6) in Comparative Example 1.

Next, the ratio N, M, L for Examples 1-4 is examined.

In Comparative Example 1, (N/M)=1, (M/L)=1. In Example 1, (N/M)=10/12=0.83, (M/L)=12/27=0.44. In Example 2, (N/M)=6/27=0.22, (M/L)=27/54=0.50. In Examples 3 and 4, (N/M)=14/10=1.4, (M/L)=10/21=0.48.

In the above Examples 1-4, 0.44≤(M/L)≤0.50. If a ±10% error margin is included in these lower and upper limits, then 0.44×90%≤(M/L)≤0.50×110% can be satisfied. That is, 0.396≤(M/L)≤0.55. Rounded to one digit of precision, 0.4≤(M/L)≤0.6.

As in Example 1 and Example 2, a smaller value of (N/M) results in a lower current flowing through the resistance elements of the sixth resistor. That is, if 0.22≤(N/M)≤0.83, the same effect as in Example 1 and Example 2 can be expected. When including a ±10% error in these lower and upper limits, the condition 0.22×90%≤(N/M)≤0.83×110% can be satisfied. That is, 0.198≤(N/M)≤0.913. When rounded to one significant figure, 0.2≤(N/M)≤0.9.

The above structure can further include dummy wiring.

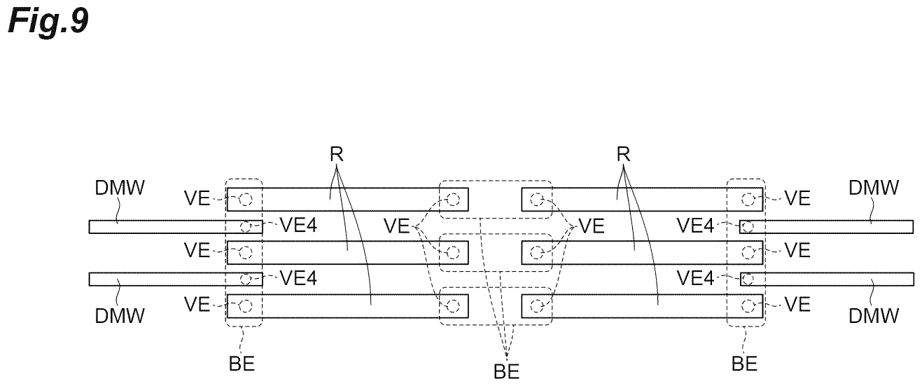

FIG. 9 is a plan configuration diagram of a resistor including dummy wiring.

Within one row, a pair of resistor elements R is connected in series via a via electrode VE and a buried electrode BE. The buried electrode BE on the left side extends over multiple rows and electrically connects one end of each resistor element R in the left column via a via electrode VE provided at the underside of the respective end of each resistor element R. Similarly, the buried electrode BE on the right side extends over multiple rows and electrically connects the other end of each resistor element R in the right column via a via electrode VE provided at the underside of the other end of the resistor element R.

The left buried electrode BE is connected, through a via electrode (VE4), to one end of the dummy wiring DMW. The right buried electrode BE is connected, through a via electrode (VE4), to one end of the dummy wiring DMW. Although the dummy wiring DMW is directly connected to the buried electrode BE, they may also be capacitively coupled.

Since the dummy wiring can be arranged to suppress local electric field concentration, the withstand voltage of the resistor chip can be increased. The length of the dummy wiring DMW can be made relatively long in the area closer to the first electrode E1 or the second electrode E2, and relatively short in the region near the first output electrode EP or the second output electrode EN. The dummy wiring may be arranged to surround the first electrode E1 and the second electrode E2. By arranging the dummy wiring so that the potential of the dummy wiring connected to the resistor gradually decreases from the first electrode E1 toward the chip edge, the withstand voltage of the resistor chip can be further increased.

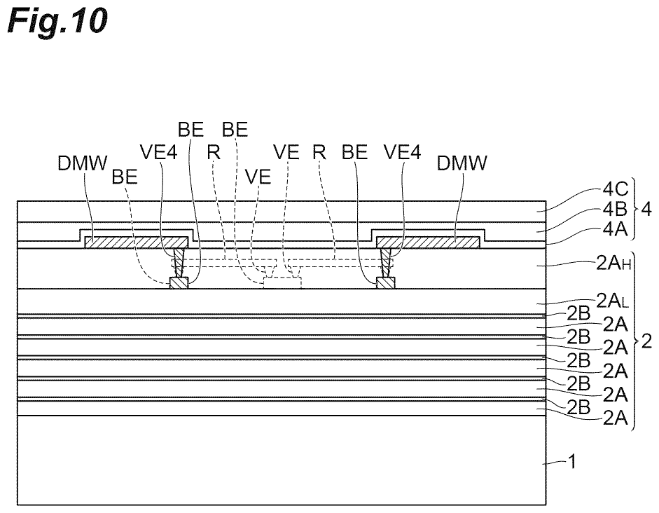

FIG. 10 is a diagram showing a vertical sectional configuration of the resistor at a position passing through the dummy wiring.

A pair of centrally located resistor elements R is connected via a central buried electrode BE and a via electrode VE. On the left side, a resistor element R is connected via a via electrode to the left buried electrode BE, which is in turn connected via a via electrode (VE4) to the left-side dummy wiring DMW. On the right side, a resistor element R is connected via a via electrode to the right buried electrode BE, which is in turn connected via a via electrode (VE4) to the right-side dummy wiring DMW. The same connection structure for the dummy wiring DMW applies in cross sections that include other resistors.

The dummy wiring DMW is formed on the insulating layer 2 and covered by the protective film 4. The dummy wiring DMW, the first output electrode EP, the reference electrode EG, and the second output electrode EN can all be formed at the same height (i.e., on the same layer).

Next, the materials for each component are described.

The semiconductor substrate 1 (FIGS. 6A, 6B and 10) can be conductive. For example, the impurity concentration of the semiconductor substrate 1 may be from 5×10¹³ (cm⁻³) to 5×10¹⁴ (cm⁻³). The thickness of the semiconductor substrate 1 may be 50 μm or more and 800 μm or less. Silicon (Si) can be used as the substrate material, but a compound semiconductor such as SiC or SiGe may also be used.

The material of the resistive layer (straight-shaped resistor) constituting the resistor R is made of a resistive material with a higher resistivity than polysilicon. Specifically, the material of the resistor (resistive layer) includes chromium (Cr) and silicon (Si), and is CrSi, CrSiC, or CrSiN. Other materials can also be used. That is, the material of the resistive layer constituting the resistor can specifically include at least one metal compound selected from the group consisting of CrSi, CrSiN, CrSiO, TaN, and TiN. The resistive layer constituting the resistor can be formed using a sputtering method or the like, using a target containing the resistive material. Depending on the type of material of the resistor R, a plating method can also be used. The material of the resistor R may be composed of a single resistive material or a combination of multiple resistive materials. The thickness Rd of each resistive layer constituting the resistor R can be set to 1 nm≤Rd≤5 nm. When the thickness Rd is at or below the upper limit, the resistance value can be sufficiently high, and when it is at or above the lower limit, the durability and strength of the resistive layer can be maintained.

Metals such as aluminum (Al) or copper (Cu) can be used for the first electrode E1, the second electrode E2, and the buried electrode (buried wiring). Various via electrodes can use a refractory metal such as tungsten (W), but other electrode materials can also be used.

Where an arbitrary parameter range is given by Pmin≤P≤Pmax, it is also allowable, for instance, to set (Pmin+ΔP)≤P≤(Pmax−ΔP) with ΔP=(Pmax−Pmin)×R %, and R can be set to R=10, R=20, R=30, or R=40.

(Additional Note) As described, various embodiments of the present disclosure may be specified by the following supplementary items, among others.

[A1] A semiconductor device comprising: an insulating layer 2 provided on a semiconductor substrate 1; a first resistor (R(4)) embedded in the insulating layer 2 and electrically connected to a node on a first potential side; a second resistor (R(5)) embedded in the insulating layer 2; a third resistor (R(6)) embedded in the insulating layer 2; and a reference electrode EG electrically connected to a node on a second potential side of the third resistor (R(6)), wherein the absolute value of the first potential is greater than the absolute value of the second potential, wherein the first resistor (R(4)), the second resistor (R(5)), and the third resistor (R(6)) are connected in series, wherein the first resistor (R(4)) is formed by connecting N resistors in parallel, wherein the second resistor (R(5)) is formed by connecting M resistors in parallel, wherein the third resistor (R(6)) is formed by connecting L resistors in parallel, and wherein N<L and M<L are satisfied.

[A2] The semiconductor device according to [A1], wherein N<M is satisfied.

[A3] The semiconductor device according to [A1], to claim 1, comprising: a first high-resistance part RP embedded in the insulating layer; a first low-resistance part RPS embedded in the insulating layer 2; a first electrode electrically connected to one end of the first high-resistance part RP; and a first output electrode electrically connected to a connection point between the first high-resistance part RP and the first low-resistance part RPS, wherein the first high-resistance part RP has a relatively higher resistance value than a resistance value of the first low-resistance part, wherein the reference electrode EG is electrically connected to an end portion on a side opposite to the connection point of the first low-resistance part RPS, and wherein the first low-resistance part RPS includes the first resistor (R(4)), the second resistor (R(5)), and the third resistor (R(6)).

[A4] The semiconductor device of [A3], The semiconductor device according to claim 3, comprising: a fourth resistor (R(4): RNS) embedded in the insulating layer 2 and electrically connected to a node on a third potential side; a fifth resistor (R(5): RNS) embedded in the insulating layer 2; and a sixth resistor (R(6): RNS) embedded in the insulating layer 2, wherein the reference electrode EG is electrically connected to a node on a fourth potential side of the sixth resistor (R(6): RNS), wherein an absolute value of the third potential is greater than an absolute value of the fourth potential, wherein the fourth resistor, the fifth resistor, and the sixth resistor are connected in series, wherein the fourth resistor is formed by connecting N resistors in parallel, wherein the fifth resistor is formed by connecting M resistors in parallel, and wherein the sixth resistor is formed by connecting L resistors in parallel.

[A5] The semiconductor device according to [A4], wherein N<M.

[A6] The semiconductor device according to [A5], a second high-resistance part RN embedded in the insulating layer 2; a second low-resistance part RNS embedded in the insulating layer 2; a second electrode electrically connected to one end of the second high-resistance part RN; and a second output electrode electrically connected to a connection point between the second high-resistance part RN and the second low-resistance part RNS, wherein the second high-resistance part RN has a relatively higher resistance value than a resistance value of the second low-resistance part RNS, wherein the reference electrode EG is electrically connected to an end portion on a side opposite to the connection point of the second low-resistance part RNS, and wherein the second low-resistance part RNS includes the fourth resistor, the fifth resistor, and the sixth resistor.

[A7] The semiconductor device according to any one of [A1] to [A6], wherein 0.4≤(M/L)≤0.6 is satisfied.

[A8] The semiconductor device according to [A7], wherein 0.2≤(N/M)≤0.9 is satisfied.

It is to be understood that not all aspects, advantages and features described herein may necessarily be achieved by, or included in, any one particular example. Indeed, having described and illustrated various examples herein, it should be apparent that other examples may be modified in arrangement and detail.

### REFERENCE SIGNS LIST

1: semiconductor substrate
2: insulating layer
2A: first dielectric layer
2A_{H}, 2A_{L}: dielectric layers
2B: second dielectric layer
4: protective film
4A: first protective film
4B: second protective film
4C: third protective film
10: resistor chip
10a: first inner lead
10b: second inner lead
10c: third inner lead
10d: fourth inner lead
10e: fifth inner lead
10f: sixth inner lead
10g: seventh inner lead
10h: eighth inner lead
10i: ninth inner lead
20: amplifier chip
30: case
100: semiconductor package
110: first die pad
120: second die pad
200: battery
BE: buried electrode
BEP: first wiring
BEG: second wiring
C10: resistor circuit (voltage divider circuit)
C20: voltage detection circuit
D1: recess
DMW: dummy wiring
E1: first electrode
E2: second electrode
EG: reference electrode
EG1: first reference electrode
EG2: second reference electrode
EP: first output electrode
EN: second output electrode
GND: ground potential
HV(+): first input terminal
HV(−): second input terminal
INN: second input terminal
INP: first input terminal
N3: node
R: resistor (resistor element, resistor layer)
R(Dmy): dummy resistor
RP: first high-resistance part
RPS: first low-resistance part
RN: second high-resistance part
RNS: second low-resistance part
RN1, RN2, RP1, RP2: high-resistance parts
VC: reference terminal
Vcc: power supply voltage
VE: via electrode

What is claimed is:

1. A semiconductor device comprising:
an insulating layer provided on a semiconductor substrate;
a first resistor embedded in the insulating layer and electrically connected to a node on a first potential side;
a second resistor embedded in the insulating layer;
a third resistor embedded in the insulating layer; and
a reference electrode electrically connected to a node on a second potential side of the third resistor,
wherein an absolute value of the first potential is greater than an absolute value of the second potential,
wherein the first resistor, the second resistor, and the third resistor are connected in series,
wherein the first resistor is formed by connecting N resistors in parallel,
wherein the second resistor is formed by connecting M resistors in parallel,
wherein the third resistor is formed by connecting L resistors in parallel, and
wherein N<L and M<L are satisfied.

2. The semiconductor device according to claim 1,
wherein N<M is satisfied.

3. The semiconductor device according to claim 1, comprising:
a first high-resistance part embedded in the insulating layer;
a first low-resistance part embedded in the insulating layer;
a first electrode electrically connected to one end of the first high-resistance part; and
a first output electrode electrically connected to a connection point between the first high-resistance part and the first low-resistance part,
wherein the first high-resistance part has a relatively higher resistance value than a resistance value of the first low-resistance part,
wherein the reference electrode is electrically connected to an end portion on a side opposite to the connection point of the first low-resistance part, and
wherein the first low-resistance part includes the first resistor, the second resistor, and the third resistor.

4. The semiconductor device according to claim 3, comprising:
a fourth resistor embedded in the insulating layer and electrically connected to a node on a third potential side;
a fifth resistor embedded in the insulating layer; and
a sixth resistor embedded in the insulating layer,
wherein the reference electrode is electrically connected to a node on a fourth potential side of the sixth resistor,
wherein an absolute value of the third potential is greater than an absolute value of the fourth potential,
wherein the fourth resistor, the fifth resistor, and the sixth resistor are connected in series,
wherein the fourth resistor is formed by connecting N resistors in parallel,
wherein the fifth resistor is formed by connecting M resistors in parallel, and
wherein the sixth resistor is formed by connecting L resistors in parallel.

5. The semiconductor device according to claim 4,
wherein N<M.

6. The semiconductor device according to claim 5, comprising:
a second high-resistance part embedded in the insulating layer;
a second low-resistance part embedded in the insulating layer;
a second electrode electrically connected to one end of the second high-resistance part; and
a second output electrode electrically connected to a connection point between the second high-resistance part and the second low-resistance part,
wherein the second high-resistance part has a relatively higher resistance value than a resistance value of the second low-resistance part,
wherein the reference electrode is electrically connected to an end portion on a side opposite to the connection point of the second low-resistance part, and
wherein the second low-resistance part includes the fourth resistor, the fifth resistor, and the sixth resistor.

7. The semiconductor device according to claim 1,
wherein 0.4≤(M/L)≤0.6 is satisfied.

8. The semiconductor device according to claim 2,
wherein 0.4≤(M/L)≤0.6 is satisfied.

9. The semiconductor device according to claim 3,
wherein 0.4≤(M/L)≤0.6 is satisfied.

10. The semiconductor device according to claim 4,
wherein 0.4≤(M/L)≤0.6 is satisfied.

11. The semiconductor device according to claim 5,
wherein 0.4≤(M/L)≤0.6 is satisfied.

12. The semiconductor device according to claim 6,
wherein 0.4≤(M/L)≤0.6 is satisfied.

13. The semiconductor device according to claim 7,
wherein 0.2≤(N/M)≤0.9 is satisfied.

14. The semiconductor device according to claim 8,
wherein 0.2≤(N/M)≤0.9 is satisfied.

15. The semiconductor device according to claim 9,
wherein 0.2≤(N/M)≤0.9 is satisfied.

16. The semiconductor device according to claim 10,
wherein 0.2≤(N/M)≤0.9 is satisfied.

17. The semiconductor device according to claim 11,
wherein 0.2≤(N/M)≤0.9 is satisfied.

18. The semiconductor device according to claim 12,
wherein 0.2≤(N/M)≤0.9 is satisfied.
